(19) United States
(12) Patent Application Publication
(10) Pub. No.: US 2026/0093186 A1
(43) Pub. Date: Apr. 2, 2026

(54) INSPECTION SYSTEMS USING METASURFACE AND INTEGRATED OPTICAL SYSTEMS FOR LITHOGRAPHY

(71) Applicant: ASML NETHERLANDS B.V., Veldhoven (NL)

(72) Inventors: Saman JAHANI, Stamford, CT (US); Jorn Paul VAN ENGELEN, Eindhoven (NL); Roxana REZVANI NARAGHI; Irwan Dani SETIJA, Utrecht (NL)

(73) Assignee: ASML NETHERLANDS B.V., Veldhoven (NL)

(21) Appl. No.: 19/113,064

(22) PCT Filed: Sep. 15, 2023
(86) PCT No.: PCT/EP2023/075424

§ 371 Date: Mar. 19, 2025

Related U.S. Application Data
(60) Provisional application No. 63/415,246, filed on Oct. 11, 2022.

(51) Int. Cl. G03F 7/00; G03F 9/00

(52) U.S. Cl. CPC G03F 7/706851; G03F 7/706845; G03F 9/7026; G03F 7/706849; G03F 9/7088

(57) ABSTRACT

An inspection system includes an integrated optical system with a substrate, waveguide system, and couplers disposed on the substrate, first and second detectors, and a micro-structured illumination adjuster. The integrated optical system receives first to fourth portions of illumination scattered from a target having corresponding first to fourth wavelengths. The couplers launch respective portions into the waveguide system. The first and second wavelengths are different from the third and fourth wavelengths. The first detector receives a combination of the first and second portions to generate a first measurement signal. The second detector receives a combination of the third and fourth portions to generate a second measurement signal. The micro-structured illumination adjuster includes micro-structured regions to direct the portions to corresponding couplers.

### CROSS-REFERENCE TO RELATED APPLICATIONS

This application claims priority of U.S. application 63/415,246 which was filed on 11 Oct. 2022 and which is incorporated herein in its entirety by reference.

### FIELD

The present disclosure relates to inspection systems, for example, alignment sensors for wafer positioning in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, alignment positions of one or more alignment marks can be measured. A lithographic system can output only a finite number of fabricated devices in a given timeframe due to a number of limitations. One example limitation is speed of alignment measurement. While it is possible to implement multiple inspection sensors in parallel inside a lithographic apparatus to speed up inspection of multiple targets, conventional sensors used in lithographic metrology can be large and costly due to their bulk optics, hindering their scalability. Furthermore, optical inspection using multiple photon wavelengths can present some design challenges.

### SUMMARY

Accordingly, it is desirable to improve fabrication throughput and accuracy. For example, aspects of optical system described herein can be used to construct scalable and accurate inspection systems that are capable of using multiple photon wavelengths simultaneously.

In some aspects, an inspection system can comprise an integrated optical system, first and second detectors, and a micro-structured illumination adjuster. The integrated optical system can comprise a substrate, waveguide system, and first, second, third, and fourth grating couplers. The integrated optical system can be configured to receive, direct, and couple first, second, third, and fourth portions of illumination scattered by a target. The first, second, third and fourth portions can have corresponding first, second, third, and fourth wavelengths. The waveguide system can be disposed on the substrate. The first grating coupler can be disposed on the substrate and can be configured to launch the first portion into the waveguide system based on the first wavelength. The second grating coupler can be disposed on the substrate and can be configured to launch the second portion into the waveguide system based on the second wavelength. The first and second wavelengths can be same. The third grating coupler can be disposed on the substrate and can be configured to launch the third portion into the waveguide system based on the third wavelength. The first and third wavelengths can be different. The fourth grating coupler can be disposed on the substrate and can be configured to launch the fourth portion into the waveguide system based on the fourth wavelength. The third and fourth wavelengths can be same. The first detector can be configured to receive a combination of the first and second portions via the waveguide system and to generate a first measurement signal comprising information of the phase delays of the first and second portions. The second detector can be configured to receive a combination of the third and fourth portions via the waveguide system and to generate a second measurement signal comprising information of the phase delays of the third and fourth portions. The micro-structured illumination adjuster can comprise first, second, third, and fourth micro-structured regions configured to direct corresponding ones of the first, second, third, and fourth portions to corresponding ones of the first, second, third, and fourth grating couplers.

In some aspects, an inspection system can comprise an integrated optical system, first and second detectors, and a micro-structured illumination adjuster. The integrated optical system can comprise a substrate, a waveguide system, and first and second grating couplers. The integrated optical system can be configured to receive, direct, and couple first and second portions of illumination scattered by a target. The first and second portions can have corresponding first and second wavelengths. The waveguide system can be disposed on the substrate. The first grating coupler can be disposed on the substrate and can be configured to launch the first portion into the waveguide system based on the first wavelength. The second grating coupler can be disposed on the substrate and can be configured to launch the second portion into the waveguide system based on the second wavelength. The first and second wavelengths can be different. The first detector can be configured to receive the first portion via the waveguide system and to generate a first measurement signal based on an intensity of the first portion. The second detector can be configured to receive the second portion via the waveguide system and to generate a second measurement signal based on an intensity of the second portion. The micro-structured illumination adjuster can comprise first and second micro-structured regions configured to direct corresponding ones of the first and second portions to corresponding ones of the first and second grating couplers.

In some aspects, a lithographic apparatus can comprise an illumination system, a projection system, and an inspection system. The illumination system can be configured to illuminate a pattern of a patterning device. The projection system can be configured to project an image of the pattern onto a substrate. The inspection system can comprise an integrated optical system, first and second detectors, and a micro-structured illumination adjuster. The integrated optical system can comprise a substrate, a waveguide system, and first and second grating couplers. The integrated optical system can be configured to receive, direct, and couple first and second portions of illumination scattered by a target on the substrate. The first and second portions can have corresponding first and second wavelengths. The waveguide system can be disposed on the substrate. The first grating coupler can be disposed on the substrate and can be configured to launch the first portion into the waveguide system based on the first wavelength. The second grating coupler can be disposed on the substrate and can be configured to launch the second portion into the waveguide system based on the second wavelength. The first and second wavelengths can be different. The first detector can be configured to receive the first portion via the waveguide system and to generate a first measurement signal based on an intensity of the first portion. The second detector can be configured to receive the second portion via the waveguide system and to generate a second measurement signal based on an intensity of the second portion. The micro-structured illumination adjuster can comprise first and second micro-structured regions configured to direct corresponding ones of the first and second portions to corresponding ones of the first and second grating couplers.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A and 4B show inspection apparatuses, according to some aspects.

FIGS. 5-9 show integrated optical systems, according to some aspects.

FIGS. 10A, 10B, 10C, and 10D show periodic structures for a grating coupler, according to some aspects.

FIGS. 11A and 11B show a unit cell of a metasurface, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

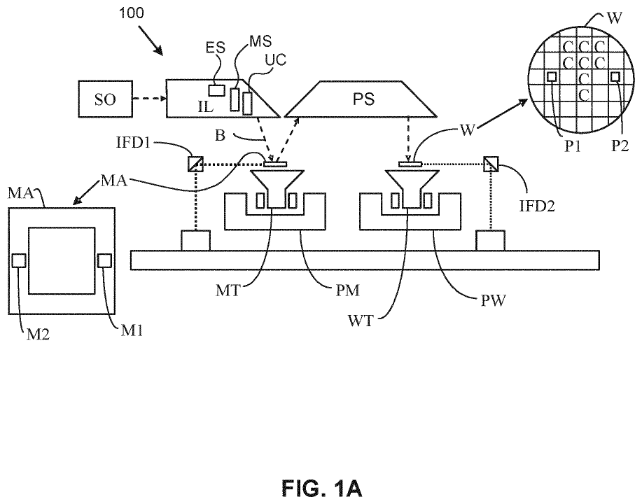

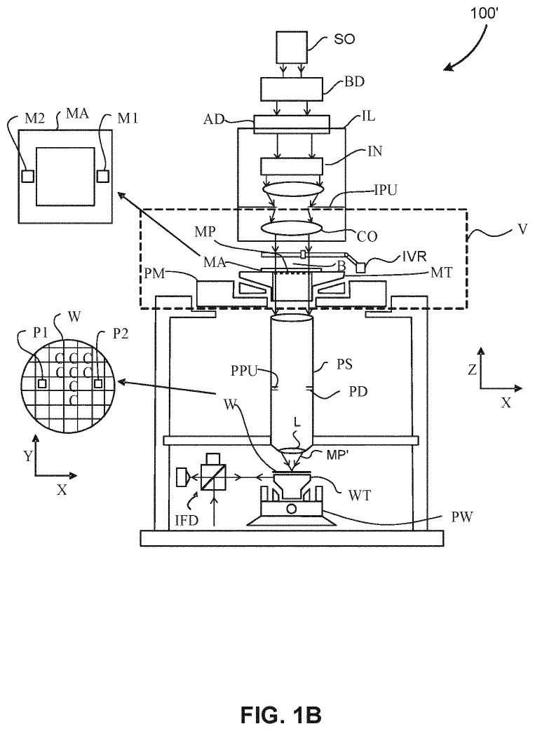

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further aspect, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

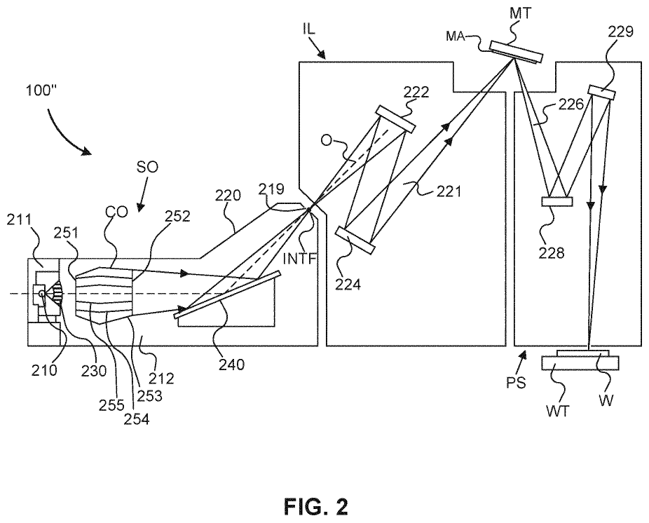

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

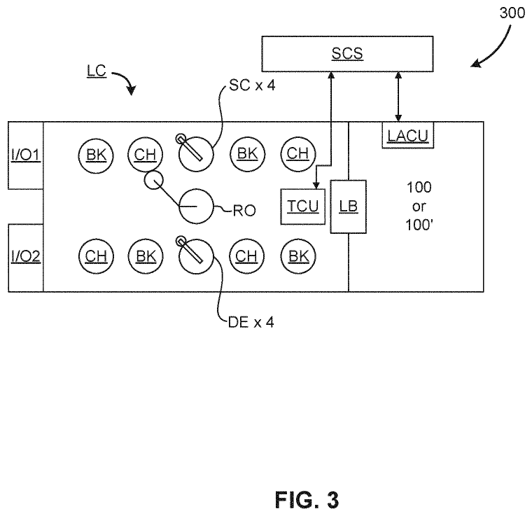

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre-and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

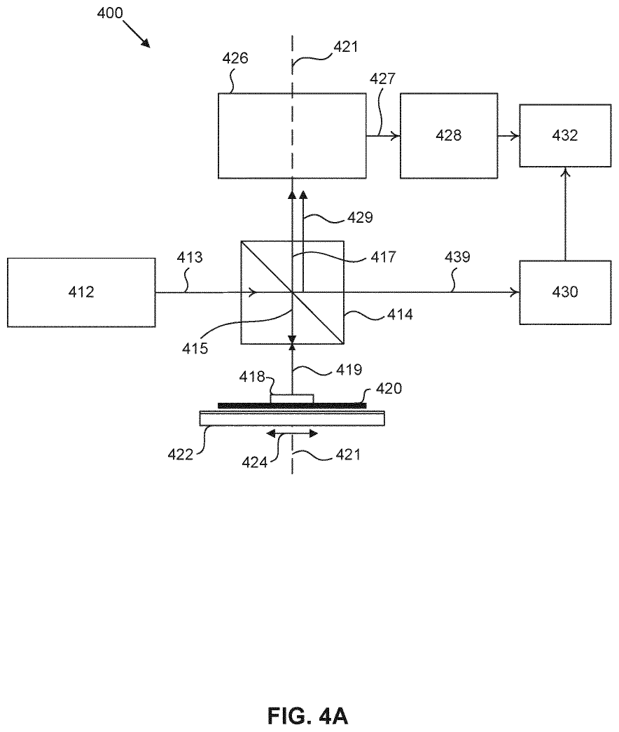

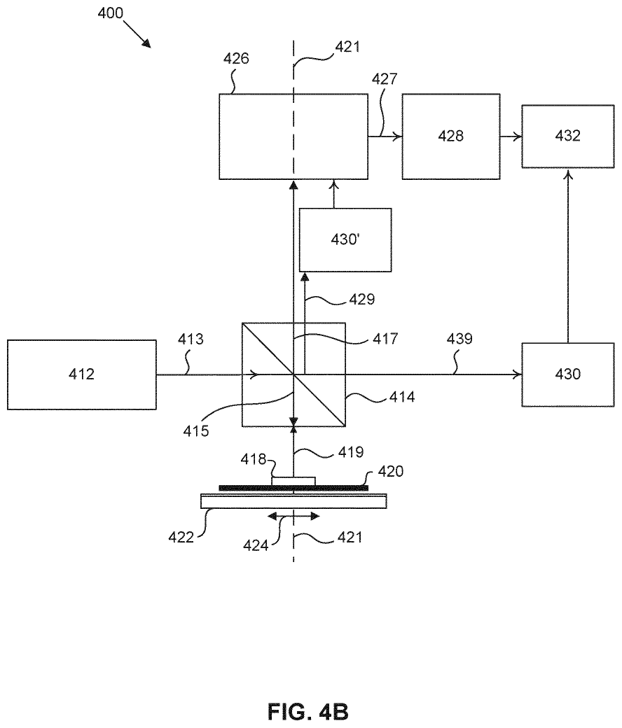

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and a processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 can receive and analyze information from detector 428 and beam analyzer 430.

### Example Integrated Optical Systems Using Metasurfaces

In some aspects, the term “throughput” can be used to characterize a rate of lithographic fabrication. For example, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each process encompasses choices in technology that compromise between qualities (e.g., sub-nanometer accuracy, high yield) and drawbacks (e.g., slower fabrication, cost). An example process directed to improving accuracy can include inspection of printed marks on a substrate. As described above, an inspection apparatus can be used to ascertain a conformity of a printed pattern on a substrate or to align a substrate in order to properly receive a new pattern. However, the inspection processes can greatly affect throughput (e.g., seeking higher accuracy can increase inspection duration, resulting in reduced throughput). Further examples of integrated optical systems can be found in WO 2021/058571, published Apr. 1, 2021, which is incorporated by reference herein in its entirety.

In some aspects, a plurality of targets can be measured in conjunction with lithographic processes. Throughput can be enhanced by increasing the speed of inspecting multiple targets. While it is possible to implement multiple inspection sensors in parallel inside a lithographic apparatus to speed up inspection of multiple targets, conventional sensors used in lithographic metrology can be large and costly due to their bulk optics, hindering their scalability. A solution can be to implement a sensor that uses a different operating principle, for example, integrated optics. Terms such as “integrated optics,” “integrated optical system,” “integrated optical circuit,” “integrated photonics system,” “photonic integrated circuit,” or the like, can be used to refer to integrated devices that can propagate optical signals. For example, an integrated optical device can comprise waveguides disposed on a substrate. The waveguides can guide optical signals to other areas of the substrate, where the optical signals can be received for conversion to measurement information. Integrated optics can be made extremely small compared to bulky free-space optics and at a fraction of the cost. Therefore, sensors based on integrated optics can be a scalable solution to increase the speed of inspecting multiple marks.

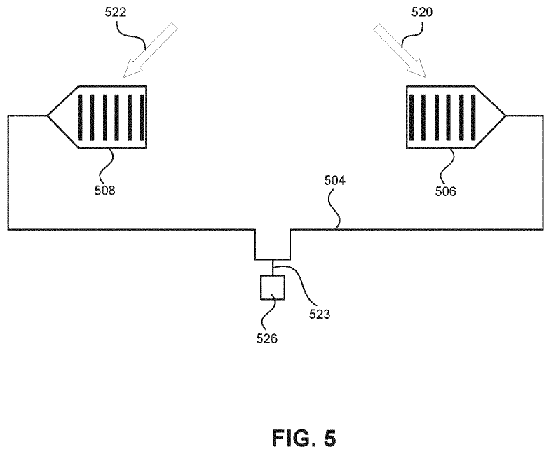

FIG. 5 shows an integrated optical system 500, according to some aspects. In some aspects, integrated optical system 500 can be used to replace at least a portion of a detection branch of inspection apparatus 400 (FIGS. 4A and 4B). The term “detection branch,” or the like, can refer to the portion of an inspection apparatus that includes devices that guide and/or receive illumination scattered from a target (e.g., diffraction radiation beam 419 from target 418 (FIGS. 4A and 4B)). Similarly, the term “illumination branch,” or the like, can refer to the portion of an inspection apparatus that includes devices that source and/or guide illumination toward a target (e.g., radiation sub-beam 415 toward target 418 (FIGS. 4A and 4B)). It should be appreciated that an illumination branch can be implemented as integrated optics. In some aspects, portions of the illumination branch and detection branch can be implemented on the same substrate (e.g., a shared integrated optical system).

In some aspects, integrated optical system 500 can comprise grating couplers 506 and 508 (e.g., first and second grating couplers) and a waveguide system 504. Elements of integrated optical system 500 can be disposed on a substrate (not shown). Integrated optical system 500 can also comprise a detector 526. Detector 526 can be an integrated element or a separate element (e.g., not integrated on the substrate). Waveguide system 504 can comprise combiner 523.

In some aspects, enumerative adjectives (e.g., “first,” “second,” “third,” or the like) can be used to distinguishing like elements without establishing an order, hierarchy, or quantity (unless otherwise noted). For example, the terms “first grating coupler” and “second grating coupler” can distinguish two grating couplers without specifying a particular order, hierarchy, or an upper or lower bound for the total number of grating couplers. Furthermore, an element in a drawing is not limited to any particular enumerative adjective. For example, grating coupler 506 can be referred to as a first grating coupler in some aspects or a second grating coupler in some other aspects.

In some aspects, an illumination source can generate illumination for irradiating a target (e.g., as described in reference to FIGS. 4A and 4B). The target can scatter the illumination (e.g., as one or more diffraction orders, 0^{th} order, ±1 order, or the like). The scattered illumination can be received at integrated optical system 500—illustrated as scattered illumination 520 and 522 (e.g., +1 and −1 diffraction orders, +2 and −2 diffraction orders, or the like). Scattered illumination 520 can be referred to as a first portion of the scattered illumination. Scattered illumination 522 can be referred to as a second portion of the scattered illumination. Grating coupler 506 can couple scattered illumination 520 into waveguide system 504. Grating coupler 508 can couple scattered illumination 522 into waveguide system 504. Combiner 523 can combine the received scattered illumination 520 and 522 (e.g., to perform interferometry). The combined illumination can be received at detector 526. Detector 526 can generate a measurement signal based on the combined illumination.

It is instructive to consider an overview of a process for performing a measurement that relies on a changing characteristic of illumination (e.g., interferometry). As a spot of illumination is moved/scanned across target 418 (FIGS. 4A and 4B), the phases of scattered illumination 520 and 522 can evolve over time due to the scanning. As scattered illumination 520 and 522 are interfered (due to combiner 523), the scanning motion of the illumination spot can cause the detected illumination at detector 526 to have AC modulation characteristics. That is, the measurement signal generated by detector 526 can be an AC signal. A property of target 418 (FIGS. 4A and 4B) (e.g., an alignment position) can be determined from the characteristics of the AC nature of the measurement signal (e.g., intensity). Characteristics can include a phase and/or amplitude of modulation of the signal intensity. For example, the measurement signal can include information of phase delays of scattered illumination 520 and 522. Properties of the inspected target can be determined therefrom (e.g., a position of the target).

In some aspects, optical inspection of a target on a wafer can be performed using a plurality of colors (or wavelengths) of illumination. A given wavelength can provide information about the target that many not be readily apparent with another wavelength. As used herein, concepts directed to “multiple wavelengths,” “multiple photon frequencies,” “multiple parameter values,” or the like, can be used to characterize narrowband values in the pertinent property or parameter. In a non-limiting example of a wavelength parameter, a first wavelength can be characterized as comprising a narrowband having a first central wavelength. A second wavelength can similarly be characterized as comprising a narrowband having a second central wavelength. A characterization of the first wavelength as being different from the second wavelength can be interpreted as the first central wavelength being different from the second central wavelength.

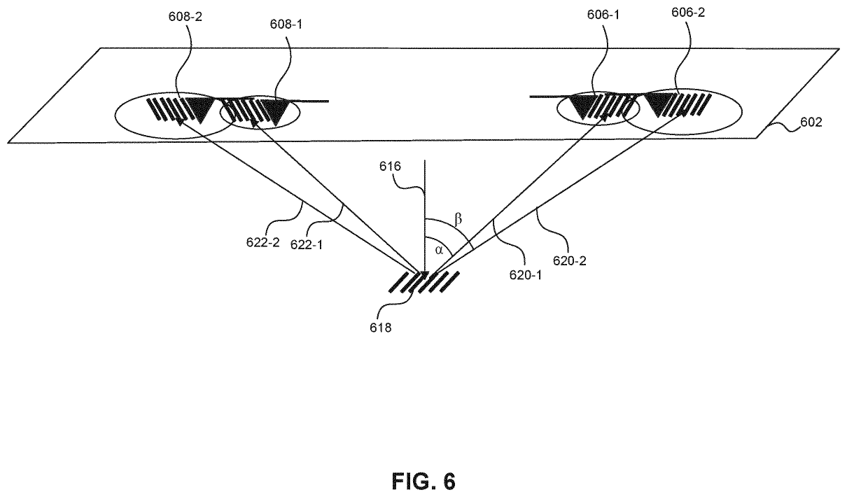

In some aspects, it is understood that combiners and detectors can scale along with the number of grating couplers. Implementations with additional grating couplers will be described in reference to FIGS. 6-9.

In some aspects, using multiple wavelengths to irradiate a target can constrain the layout of grating couplers. An example some constraints is described below in reference to FIG. 6.

FIG. 6 shows an integrated optical system 600, according to some aspects. In some aspects, integrated optical system 600 can comprise structures and functions similar to integrated optical system 500 that were described in reference to FIG. 5. Therefore, unless otherwise noted, descriptions of elements of FIG. 5 can also apply to corresponding elements of FIG. 6 (e.g., reference numbers sharing the two right-most numeric digits) and will not be rigorously reintroduced. Examples of such elements in FIG. 6 can include grating couplers 606 and 608 and illumination 620 and 622.

In some aspects, integrated optical system 600 can comprise a substrate 602 on which grating couplers 606 and 608 are disposed. Grating couplers 606 and 608 are each a plurality of grating couplers. For example, grating couplers 606 are drawn and labeled as 606-1 and 606-n (n=2 in the non-limiting example illustrated in FIG. 6; that is, n can be two or more). Similarly, grating couplers 608 are drawn and labeled as grating couplers 608-1 and 608-2. The introduction of additional grating couplers compared to FIG. 5 can be to account for a sensitivity of the grating coupler structures to different wavelengths. That is, a grating coupler can be engineered to have a given structure size and a given shape such that illumination of a certain wavelength(s) is able to be launched into a waveguide. Different grating couplers with different structural parameters can be used for the different wavelengths (e.g., a first grating coupler can launch illumination having a first wavelength into a waveguide system based on that first wavelength).

In some aspects, a beam of illumination 616 can be directed toward a target 618 (e.g., a grating target, alignment mark, or the like). The interaction between beam of illumination 616 and target 618 can scatter illumination along diffraction orders. The scattering angle can depend on the wavelength(s) of beam of illumination 616. For example, at a first wavelength (denoted by the suffix n=1), scattered illumination can be distributed among scattered illumination 620-1 and 622-1, which can be understood as the + and − diffraction of the same order (e.g., +1 and −1, +2 and −2, or the like). The diffraction angle for scattered illumination 620-1 and 622-1 is denoted as α. At a second wavelength (denoted by the suffix n=2), scattered illumination can be distributed among scattered illumination 620-2 and 622-2. The diffraction angle for scattered illumination 620-2 and 622-2 is denoted as β. Scattered illumination 620-1, 620-2, 622-1, and 622-2 (e.g., first, second, third, and fourth portions of scattered illumination) can be launched into a waveguide system (e.g., waveguide system 504 (FIG. 5)) for subsequent detection and analysis.

To better illustrate some problems and solutions, it is instructive to consider a non-limiting example in which the diffraction orders are constrained to be 1^{st} order (i.e., +1 or −1). The variability due to wavelengths can be better appreciated by eliminating variability of diffraction orders (e.g., eliminating differences in diffraction angles associated with 1^{st} order and 2^{nd} order).

In some aspects, beam of illumination 616 can include multiple wavelengths. Some commercially available alignment sensors are capable of inspecting alignment marks using twelve wavelengths that cover a spectrum including infrared (IR), visible, and ultraviolet (UV). When a broad spectrum of wavelengths is used, target 618 is capable of scattering illumination along a large range of diffraction angles. A problem can arise at large diffraction angles that lie beyond the angle β shown in FIG. 6. The positional arrangement of grating couplers relies on the diffraction angles. Some positions of grating couplers may enlarge the footprint of integrated optical system 600, which is counter to the goal of miniaturizing inspection systems. Another problem may be that some grating couplers may need to be positioned so close together that they are in conflict (overlap). This can happen when diffraction angles for two wavelengths are close and the beam cross-section for each wavelength at the target is large (e.g., α and β can be similar in instances where the two wavelengths are similar and/or the grating pitch is large). This causes an overlap between the beams for the two wavelengths. Aspects of the present disclosure address such problems arising from the use of multiple wavelengths.

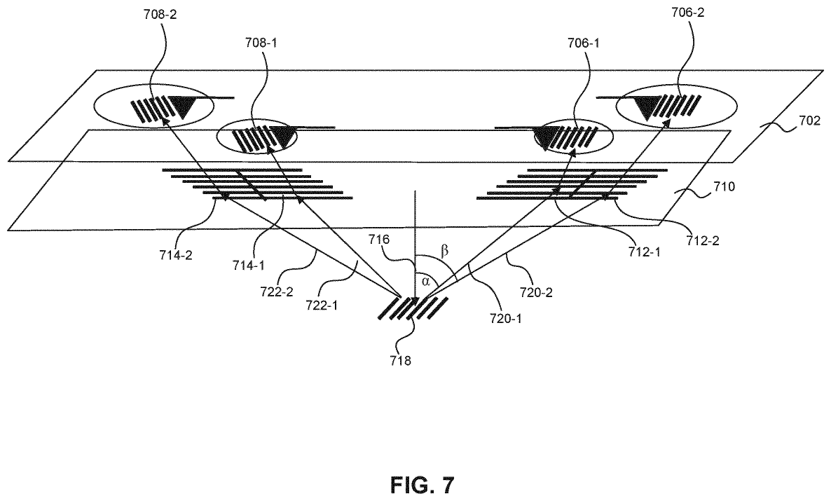

FIG. 7 shows an integrated optical system 700, according to some aspects. In some aspects, integrated optical system 700 can comprise structures and functions similar to integrated optical systems 500 and 600 that were described in reference to FIGS. 5 and 6. Therefore, unless otherwise noted, descriptions of elements of FIGS. 5 and 6 can also apply to corresponding elements of FIG. 7 (e.g., reference numbers sharing the two right-most numeric digits) and will not be rigorously reintroduced. Examples of such elements in FIG. 7 can include substrate 702, grating couplers 706-1, 706-2, 708-1, and 708-2, beam of illumination 716, target 718, and scattered illumination 720-1, 720-2, 722-1, and 722-2.

In some aspects, integrated optical system 700 can comprise a micro-structured illumination adjuster 710 comprising micro-structured regions 712-1, 712-2, 714-1, and 714-2 (as before, the suffixes 1, 2, . . . , n can denote associations to different wavelengths). Micro-structured illumination adjuster 710 can be disposed on substrate 702. Micro-structured illumination adjuster 710 can be disposed between substrate 702 and target 718. Micro-structured region 712-1 can be disposed in the path of scattered illumination 720-1 having a diffraction angle α (e.g., a first portion of scattered illumination from target 718). The structure of micro-structured region 712-1 can be engineered such that scattered illumination 720-1 is redirected toward grating coupler 706-1. The structure of micro-structured region 712-2 can be engineered such that scattered illumination 720-2 is redirected toward grating coupler 706-2. The structure of micro-structured region 714-1 can be engineered such that scattered illumination 722-1 is redirected toward grating coupler 708-1. The structure of micro-structured region 714-2 can be engineered such that scattered illumination 722-2 is redirected toward grating coupler 708-2. In other words, first, second, third, and fourth micro-structured regions can direct corresponding ones of the first, second, third, and fourth portions of the scattered illumination to corresponding ones of the first, second, third, and fourth grating couplers.

In some aspects, micro-structured regions 712-1, 712-2, 714-1, and 714-2 can comprise gratings specifically engineered for individual wavelengths used in beam of illumination 716. For example, a micro-structured region can be a grating or a metasurface. For a grating, the grating line width and/or spacing can be comparable to the order of a corresponding wavelength in beam of illumination 716.

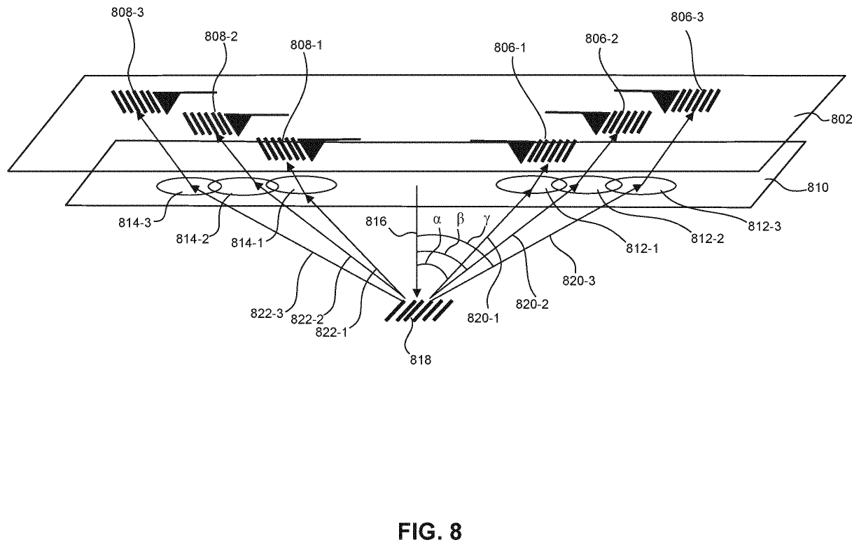

FIG. 8 shows an integrated optical system 800, according to some aspects. In some aspects, integrated optical system 800 can comprise structures and functions similar to integrated optical systems 500, 600, and 700 that were described in reference to FIGS. 5-7. Therefore, unless otherwise noted, descriptions of elements of FIGS. 5-7 can also apply to corresponding elements of FIG. 8 (e.g., reference numbers sharing the two right-most numeric digits) and will not be rigorously reintroduced. Examples of such elements in FIG. 8 can include substrate 802, grating couplers 806-1, 806-2, 808-1, and 808-2, micro-structured illumination adjuster 810, micro-structured regions 812-1, 812-2, 814-1, and 814-2, beam of illumination 816, target 818, scattered illumination 820-1, 820-2, 822-1, and 822-2.

In some aspects, the number of wavelengths n illustrated in FIG. 8 has been increased to 3 (non-limiting example; more wavelengths can be used), compared to the two wavelengths illustrated in FIG. 7. Accordingly, additional grating couplers are disposed on substrate 802, such as grating couplers 806-3 and 808-3 (806-n and 808-n, where n=3). The diffraction angle associated with the third wavelength is denoted by γ.

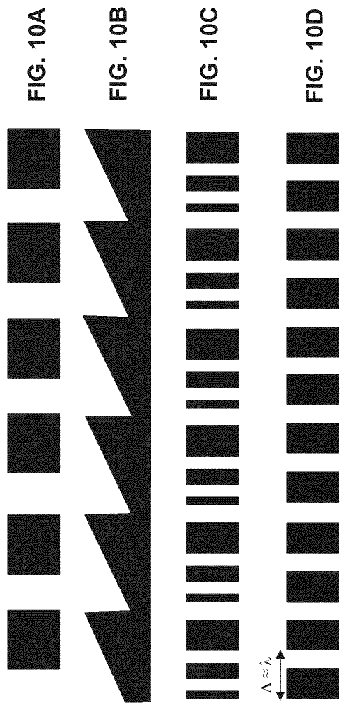

In some aspects, micro-structured illumination adjuster 810 can be a metasurface array and the micro-structured regions can be metasurface regions. A metasurface can comprise a spatially varying metasurface. A metasurface is a form of metamaterial. Metamaterials are a class of functional materials that are designed using micro and/or nanoscale patterns or structures. The structure patterns can influence illumination to interact with the metamaterial in a manner that is different from a conventional non-patterned material (an example of an interaction with a conventional non-patterned material is refraction at a glass interface). Some examples of micro and nanoscale patterns for metasurfaces are described in reference to FIG. 10.

In some aspects, the structures of a metasurface can be engineered to adjust phase, amplitude, and/or polarization of illumination that is received at the metasurface. The metasurface can control a direction of the received radiation based on the adjusting of the phase, amplitude, and/or polarization of the incident beam.

In some aspects, using micro-structured regions can circumvent the use of bulky lenses to condition illumination. In conventional optical sensors, bulk optics like lenses tend to increase the size of the sensor, which is counter to the goal of miniaturization. Since metasurfaces are capable of altering phase, amplitude, and/or polarization of illumination in a predictable manner, metasurfaces can condition illumination (e.g., collimate, focus, phase correction, correction of optical aberration, or the like) without relying on bulk optics. That is, in some aspects, there is no lens disposed between micro-structured illumination adjuster 810 and target 810.

In some aspects, micro-structured illumination adjuster 810 can be disposed on substrate 802. Micro-structured illumination adjuster 810 can comprise a transparent bulk material with a thickness to such that space for illumination propagation is formed between micro-structured illumination adjuster 810 and substrate 802. Micro-structured regions 812-1, 812-2, 812-3, 814-1, 814-2, and 814-3 can comprise metasurfaces that, respectively, direct scattered radiation 820-1, 820-2, 820-3, 822-1, 822-2, and 822-3 toward corresponding ones of grating couplers 806-1, 806-2, 806-3, 808-1, 808-2, and 808-3.

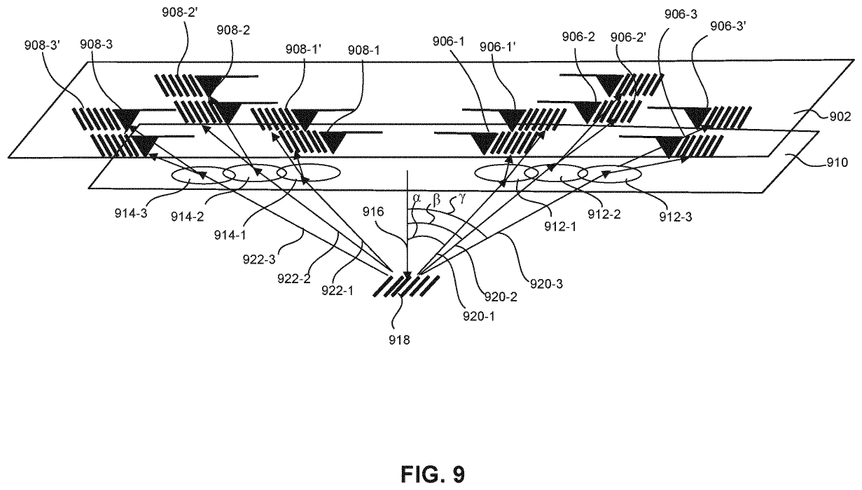

FIG. 9 shows an integrated optical system 900, according to some aspects. In some aspects, integrated optical system 900 can comprise structures and functions similar to integrated optical systems 500, 600, 700, and 800 that were described in reference to FIGS. 5-8. Therefore, unless otherwise noted, descriptions of elements of FIGS. 5-8 can also apply to corresponding elements of FIG. 9 (e.g., reference numbers sharing the two right-most numeric digits) and will not be rigorously reintroduced. Examples of such elements in FIG. 9 can include substrate 902, grating couplers 906-1, 906-2, 906-3, 908-1, 908-2, and 908-3, micro-structured illumination adjuster 910, micro-structured regions 912-1, 912-2, 912-3, 914-1, 914-2, and 914-3, beam of illumination 916, target 918, scattered illumination 920-1, 920-2, 920-3, 922-1, 922-2, and 922-3.

In some aspects, micro-structured illumination adjuster 910 can be engineered to direct and/or split illumination based on a polarization of the illumination. Each of scattered illumination 920-1, 920-2, 920-3, 922-1, 922-2, and 922-3 can be polarized along a given direction. Interaction between scattered illumination 920-1, 920-2, 920-3, 922-1, 922-2, and 922-3 and micro-structured regions 912-1, 912-2, 912-3, 914-1, 914-2, and 914-3 can cause scattered illumination 920-1, 920-2, 920-3, 922-1, 922-2, and 922-3 to be divided in two. The divided scattered illumination can be separated into orthogonally polarized components.

In some aspects, the number of grating couplers is doubled (e.g., twelve shown in FIG. 9 compared to the six shown in FIG. 8) due to the doubling of illumination paths caused by the division of polarization components. Additional grating couplers are denoted with a prime label (e.g., grating couplers 906-1′, 906-2′, 906-3′, 908-1′, 908-2′, and 908-3′). In this manner, metasurfaces can be used to engineer the directions of scattered illumination. In turn, a designer of integrated optical system 900 has more freedom in terms of optimal placement of grating couplers as well as the ability to make integrated optical system 900 as compact as possible.

FIGS. 5-9 illustrate interference-type inspection systems that analyze input from two opposing diffraction orders (e.g., +1 and −1). However, the present disclosure is not limited to such paired detection. For example, unpaired grating coupler aspects can also implement micro-structured illumination adjusters. As a non-limiting example, an aspect can implement the right half of FIG. 8 without the left-side (e.g., implementing grating couplers 806-1, 806-2, and/or 806-3 along with micro-structured regions 812-1, 812-2, and/or 812-3 while omitting the grating couplers and meta-surface regions on the left of target 818).

In some aspects, the ability to optically inspect a target with a simultaneity of different illumination parameters (e.g., different wavelengths and/or polarizations) allows for increased throughput by reducing inspection time. For example, a slower method of optical inspection can involve using beam of illumination 916 that cycles through the different wavelengths one-by-one sequentially.

FIGS. 10A, 10B, 10C, and 10D show periodic structures for a grating coupler, according to some aspects. In some aspects, a grating coupler can comprise periodic blocks or lines (FIG. 10A). A grating coupler can comprise a sawtooth periodic structure (FIG. 10B). A grating coupler can comprise a compound periodic structure having a unit cell and, within the unit cell, additional structural features (FIG. 10C). FIG. 10D is similar to FIG. 10A, but having a smaller periodicity. The pitch Λ of periodic structures (or unit cells) can be comparable to one wavelength λ (or more) of the wavelengths used in an optical inspection operation.

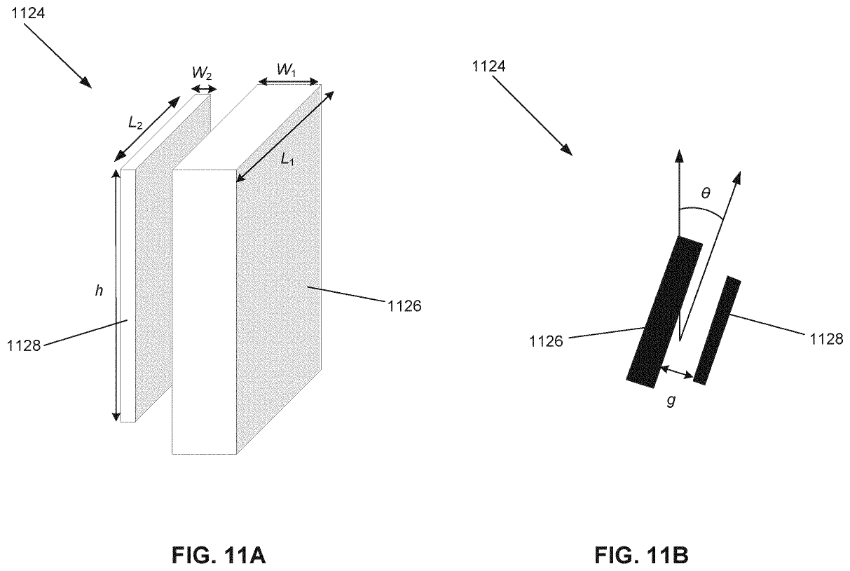

FIGS. 11A and 11B show a unit cell 1124 of a metasurface, according to some aspects. In some aspects, unit cell 1124 can comprise unit cell structures 1126 and 1128 (e.g., first and second unit cell structures). Unit cell structures 1126 and 1128 can each have a shape and volume of a rectangular prism. Unit cell structures 1126 and 1128 are not limited to rectangular geometries. For example, geometries can be elliptical, asymmetric, or the like. Unit cell 1124 is not limited to two substructures. For example, there can be one or more structures (e.g., three structures). The shapes and number of structures can be designed to illicit a desired interaction between the metasurface and the incident illumination). Unit cell structure 1126 can have a height h, a length L₁, and a width W₁. Unit cell structure 1128 can have a height (e.g., equal or not equal to h), a length L₂, and a width W₂. Unit cell structure 1126 can have a size that is different from unit cell structure 1128. Unit cell structures 1126 and 1128 can be separated by a gap g. One or both of unit cell structures 1126 and 1128 can be slanted at an angle θ with respect to a plane of the metasurface. Unit cell 1124 can be iterated across the metasurface to form a periodic structure.

The embodiments may further be described using the following clauses:
1. An inspection system comprising:
   an integrated optical system configured to receive, direct, and couple first, second, third, and fourth portions of illumination scattered by a target, the first, second, third and fourth portions having corresponding first, second, third, and fourth wavelengths, the integrated optical system comprising:
      a substrate;
      a waveguide system disposed on the substrate;
      a first grating coupler disposed on the substrate and configured to launch the first portion into the waveguide system based on the first wavelength;
      a second grating coupler disposed on the substrate and configured to launch the second portion into the waveguide system based on the second wavelength, the first and second wavelengths being same;
      a third grating coupler disposed on the substrate and configured to launch the third portion into the waveguide system based on the third wavelength, the first and third wavelengths being different; and
      a fourth grating coupler disposed on the substrate and configured to launch the fourth portion into the waveguide system based on the fourth wavelength, the third and fourth wavelengths being same;
   a first detector configured to receive a combination of the first and second portions via the waveguide system and to generate a first measurement signal comprising information of the phase delays of the first and second portions;
   a second detector configured to receive a combination of the third and fourth portions via the waveguide system and to generate a second measurement signal comprising information of the phase delays of the third and fourth portions; and
   a micro-structured illumination adjuster comprising first, second, third, and fourth micro-structured regions configured to direct corresponding ones of the first, second, third, and fourth portions to corresponding ones of the first, second, third, and fourth grating couplers.
2. The inspection system of clause 1, further comprising:
   a processor configured to:
      analyze the first and second measurement signals; and
      determine a position of the target based on the information of the phase delays of the first, second, third, and fourth portions.
3. The inspection system of clause 1, wherein the inspection system is an optical system configured to:
   direct illumination toward the target to generate the first, second, third, and fourth portions; and
   scan the directed illumination across the target.
4. The inspection system of clause 1, wherein:
   the integrated optical system is further configured to receive, direct, and couple fifth and sixth portions of the illumination scattered by the target, the fifth and sixth portions having corresponding fifth and sixth wavelengths;
   the integrated optical system further comprises:
      a fifth grating coupler disposed on the substrate and configured to launch the fifth portion into the waveguide system based on the fifth wavelength, the fifth wavelength being different from the first and third wavelengths; and
      a sixth grating coupler disposed on the substrate and configured to launch the sixth portion into the waveguide system based on the sixth wavelength, the fifth and sixth wavelength being same;
   the inspection system further comprises a third detector configured to receive a combination of the fifth and sixth portions via the waveguide system and to generate a third measurement signal comprising information of the phase delays of the fifth and sixth portions; and
   the micro-structured illumination adjuster further comprises fifth and sixth micro-structured regions configured to direct corresponding ones of the fifth and sixth portions to corresponding ones of the fifth and sixth grating couplers.
5. The inspection system of clause 1, wherein at least the first micro-structured region of the micro-structured illumination adjuster is polarization-sensitive and configured to split and direct illumination based on polarization.
6. The inspection system of clause 1, wherein the first, second, third, and fourth micro-structured regions are gratings.
7. The inspection system of clause 1, wherein the micro-structured illumination adjuster is a metasurface array and the first, second, third, and fourth micro-structured regions are metasurface regions.
8. The inspection system of clause 7, wherein the metasurface regions comprise periodic structures configured to adjust a phase, amplitude, and/or polarization of the first, second, third, and fourth portions.
9. The inspection system of clause 8, wherein the metasurface regions are configured to control directions of the first, second, third, and fourth portions based on the adjusting of the phase, amplitude, and/or polarization.
10. The inspection system of clause 7, wherein the metasurface regions are configured to control focus of, and/or apply phase correction to, the first, second, third, and fourth portions or an optical aberration.
11. The inspection system of clause 1, wherein there is no lens disposed between the micro-structured illumination adjuster and the target.
12. An inspection system comprising:
   an integrated optical system configured to receive, direct, and couple first and second portions of illumination scattered by a target, the first and second portions having corresponding first and second wavelengths, the integrated optical system comprising:
      a substrate;
      a waveguide system disposed on the substrate;
      a first grating coupler disposed on the substrate and configured to launch the first portion into the waveguide system based on the first wavelength; and
      a second grating coupler disposed on the substrate and is configured to launch the second portion into the waveguide system based on the second wavelength, the first and second wavelengths being different;
   a first detector configured to receive the first portion via the waveguide system and to generate a first measurement signal based on an intensity of the first portion;
   a second detector configured to receive the second portion via the waveguide system and to generate a second measurement signal based on an intensity of the second portion; and
   a micro-structured illumination adjuster comprising first and second micro-structured regions configured to direct corresponding ones of the first and second portions to corresponding ones of the first and second grating couplers.
13. The inspection system of clause 12, further comprising:
   a processor configured to:
   analyze the first and second measurement signals; and
   determine a property of the target based on the intensity of the first and second portions.
14. The inspection system of clause 12, wherein the inspection system is an optical system configured to:
   direct illumination toward the target to generate the first and second portions; and scan the directed illumination across the target.
15. The inspection system of clause 12, wherein:
   the integrated optical system is further configured to receive, direct, and a third portion of the illumination scattered by the target, the third portion having a corresponding third wavelength;
   the integrated optical system further comprises a third grating coupler disposed on the substrate and configured to launch the third portion into the waveguide system based on the third wavelength, the third wavelength being different from the first and second wavelengths;
   the inspection system further comprises a third detector configured to receive the third portion via the waveguide system and to generate a third measurement signal based on an intensity of the third portion; and
   the micro-structured illumination adjuster further comprises a third micro-structured region configured to direct the third portion to the third grating coupler.
16. The inspection system of clause 12, wherein the micro-structured illumination adjuster is a metasurface array and the first and second micro-structured regions are metasurface regions comprising periodic structures configured to adjust a phase, amplitude, and/or polarization of the first and second portions.
17. The inspection system of clause 16, wherein the metasurface regions are configured to control directions of the first and second portions based on the adjusting of the phase, amplitude, and/or polarization.
18. The inspection system of clause 16, wherein the metasurface regions are configured to control focus of, and/or apply phase correction to, the first and second portions.
19. The inspection system of clause 12, wherein there is no lens disposed between the micro-structured illumination adjuster and the target.
20. A lithographic apparatus comprising:
   an illumination system configured to illuminate a pattern of a patterning device;
   a projection system configured to project an image of the pattern onto a substrate; and
   an inspection system comprising:
      an integrated optical system configured to receive, direct, and couple first and second portions of illumination scattered by a target on the substrate, the first and second portions having corresponding first and second wavelengths, the integrated optical system comprising:
         a substrate;
         a waveguide system disposed on the substrate;
         a first grating coupler disposed on the substrate and configured to launch the first portion into the waveguide system based on the first wavelength; and
         a second grating coupler disposed on the substrate and is configured to launch the second portion into the waveguide system based on the second wavelength, the first and second wavelengths being different;
      a first detector configured to receive the first portion via the waveguide system and to generate a first measurement signal based on an intensity of the first portion;
      a second detector configured to receive the second portion via the waveguide system and to generate a second measurement signal based on an intensity of the second portion; and
   a micro-structured illumination adjuster comprising first and second micro-structured regions configured to direct corresponding ones of the first and second portions to corresponding ones of the first and second grating couplers.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm. Some alignment sensors can use wavelengths between 500 and 900 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. An inspection system comprising:
an integrated optical system configured to receive, direct, and couple first, second, third, and fourth portions of illumination scattered by a target, the first, second, third and fourth portions having corresponding first, second, third, and fourth wavelengths, the integrated optical system comprising:
a substrate;
a waveguide system disposed on the substrate;
a first grating coupler disposed on the substrate and configured to launch the first portion into the waveguide system based on the first wavelength;
a second grating coupler disposed on the substrate and configured to launch the second portion into the waveguide system based on the second wavelength, the first and second wavelengths being the same;
a third grating coupler disposed on the substrate and configured to launch the third portion into the waveguide system based on the third wavelength, the first and third wavelengths being different; and
a fourth grating coupler disposed on the substrate and configured to launch the fourth portion into the waveguide system based on the fourth wavelength, the third and fourth wavelengths being the same;
a first detector configured to receive a combination of the first and second portions via the waveguide system and to generate a first measurement signal comprising information of phase delay of the first and second portions;
a second detector configured to receive a combination of the third and fourth portions via the waveguide system and to generate a second measurement signal comprising information of phase delay of the third and fourth portions; and
a micro-structured illumination adjuster comprising first, second, third, and fourth micro-structured regions configured to direct corresponding ones of the first, second, third, and fourth portions to corresponding ones of the first, second, third, and fourth grating couplers.

2. The inspection system of claim 1, further comprising a processor configured to:
analyze the first and second measurement signals; and
determine a position of the target based on the information of the phase delays of the first, second, third, and fourth portions.

3. The inspection system of claim 1, configured to:
direct illumination toward the target to generate the first, second, third, and fourth portions; and
scan the directed illumination across the target.

4. The inspection system of claim 1, wherein:
the integrated optical system is further configured to receive, direct, and couple fifth and sixth portions of the illumination scattered by the target, the fifth and sixth portions having corresponding fifth and sixth wavelengths;
the integrated optical system further comprises:
a fifth grating coupler disposed on the substrate and configured to launch the fifth portion into the waveguide system based on the fifth wavelength, the fifth wavelength being different from the first and third wavelengths; and
a sixth grating coupler disposed on the substrate and configured to launch the sixth portion into the waveguide system based on the sixth wavelength, the fifth and sixth wavelength being the same;
the micro-structured illumination adjuster further comprises fifth and sixth micro-structured regions configured to direct corresponding ones of the fifth and sixth portions to corresponding ones of the fifth and sixth grating couplers; and
the inspection system further comprises a third detector configured to receive a combination of the fifth and sixth portions via the waveguide system and to generate a third measurement signal comprising information of phase delay of the fifth and sixth portions.

5. The inspection system of claim 1, wherein at least the first micro-structured region of the micro-structured illumination adjuster is polarization-sensitive and configured to split and direct illumination based on polarization.

6. The inspection system of claim 1, wherein the first, second, third, and fourth micro-structured regions are gratings.

7. The inspection system of claim 1, wherein the micro-structured illumination adjuster is a metasurface array and the first, second, third, and fourth micro-structured regions are metasurface regions.

8. The inspection system of claim 7, wherein the metasurface regions comprise periodic structures configured to adjust a phase, amplitude, and/or polarization of the first, second, third, and fourth portions.

9. The inspection system of claim 8, wherein the metasurface regions are configured to control directions of the first, second, third, and fourth portions based on the adjustment of the phase, amplitude, and/or polarization.

10. The inspection system of claim 7, wherein the metasurface regions are configured to control focus of, and/or apply phase correction to, the first, second, third, and fourth portions or an optical aberration.

11. The inspection system of claim 1, wherein there is no lens disposed between the micro-structured illumination adjuster and the target.

12. An inspection system comprising:
an integrated optical system configured to receive, direct, and couple first and second portions of illumination scattered by a target, the first and second portions having corresponding first and second wavelengths, the integrated optical system comprising:
a substrate;
a waveguide system disposed on the substrate;
a first grating coupler disposed on the substrate and configured to launch the first portion into the waveguide system based on the first wavelength; and
a second grating coupler disposed on the substrate and configured to launch the second portion into the waveguide system based on the second wavelength, the first and second wavelengths being different;
a first detector configured to receive the first portion via the waveguide system and to generate a first measurement signal based on an intensity of the first portion;
a second detector configured to receive the second portion via the waveguide system and to generate a second measurement signal based on an intensity of the second portion; and
a micro-structured illumination adjuster comprising first and second micro-structured regions configured to direct corresponding ones of the first and second portions to corresponding ones of the first and second grating couplers.

13. The inspection system of claim 12, further comprising a processor configured to:
analyze the first and second measurement signals; and
determine a property of the target based on the intensity of the first and second portions.

14. The inspection system of claim 12, configured to:
direct illumination toward the target to generate the first and second portions; and
scan the directed illumination across the target.

15. The inspection system of claim 12, wherein:
the integrated optical system is further configured to receive, direct, and couple a third portion of the illumination scattered by the target, the third portion having a corresponding third wavelength;
the integrated optical system further comprises a third grating coupler disposed on the substrate and configured to launch the third portion into the waveguide system based on the third wavelength, the third wavelength being different from the first and second wavelengths;
the micro-structured illumination adjuster further comprises a third micro-structured region configured to direct the third portion to the third grating coupler; and
the inspection system further comprises a third detector configured to receive the third portion via the waveguide system and to generate a third measurement signal based on an intensity of the third portion.

16. The inspection system of claim 12, wherein at least the first micro-structured region of the micro-structured illumination adjuster is polarization-sensitive and configured to split and direct illumination based on polarization.

17. The inspection system of claim 12, wherein the first and second micro-structured regions are gratings.

18. The inspection system of claim 12, wherein the micro-structured illumination adjuster is a metasurface array and the first and second micro-structured regions are metasurface regions.

19. The inspection system of claim 18, wherein the metasurface regions comprise periodic structures configured to adjust a phase, amplitude, and/or polarization of the first, second, third, and fourth portions or the metasurface regions are configured to control focus of, and/or apply phase correction to, the first, second, third, and fourth portions or an optical aberration.

20. The inspection system of claim 12, wherein there is no lens disposed between the micro-structured illumination adjuster and the target.
